(19) United States
(12) Patent Application Publication
(10) Pub. No.: US 2025/0212322 A1
(43) Pub. Date: Jun. 26, 2025

(54) BUS BAR MODULE

(71) Applicant: YAZAKI CORPORATION, Tokyo (JP)

(72) Inventors: Katsunori Sato, Makinohara-shi (JP); Tatsuya Oga, Makinohara-shi (JP); Mariko Nakagawa, Makinohara-shi (JP); Masato Tanaka, Makinohara-shi (JP)

(21) Appl. No.: 18/984,818

(22) Filed: Dec. 17, 2024

(30) Foreign Application Priority Data
Dec. 25, 2023 (JP) 2023-218367

(51) Int. Cl. H05K 1/02; H01M 50/507; H01M 50/519

(52) U.S. Cl. CPC H05K 1/0277; H01M 50/507; H01M 50/519; H05K 2201/10272

(57) ABSTRACT

A bus bar module includes: a first module including a first substrate that is a flexible printed circuit, and a device connection unit that connects a circuit of the first substrate to an external device; and a second module including a second substrate configured to be connectable to the first substrate, and at least one bus bar connected to a circuit of the second substrate. The first module may have at least one bus bar connected to the circuit of the first substrate.

### CROSS-REFERENCE TO RELATED APPLICATION(S)

The present application claims priority to and incorporates by reference the entire contents of Japanese Patent Application No. 2023-218367 filed in Japan on Dec. 25, 2023.

### BACKGROUND OF THE INVENTION

### 1. Field of the Invention

The present invention relates to a bus bar module.

### 2. Description of the Related Art

Conventionally, there is a battery sensing unit including a flexible printed circuit. Japanese Patent Application Laid-open No. 2022-108301 discloses a battery sensing unit including a circuit board, a voltage detection unit capable of detecting a voltage value of a battery, and a current detection unit capable of detecting a current value of the battery. The circuit board of Japanese Patent Application Laid-open No. 2022-108301 includes a flexible printed circuit having a conductive pattern.

Concerning a bus bar module using a flexible printed circuit, there has been a demand for reducing the cost. For example, in a case where the flexible printed circuit is long, this tends to cause increases in manufacturing cost and component surface mounting-related cost. In addition, the long flexible printed circuit tends to cause increases in transportation cost and storage cost.

### SUMMARY OF THE INVENTION

An object of the present invention is to provide a bus bar module capable of reducing costs while using a flexible printed circuit.

In order to achieve the above mentioned object, a bus bar module according to one aspect of the present invention includes a first module including a first substrate that is a flexible printed circuit, and a device connection unit that connects a circuit of the first substrate to an external device; and a second module including a second substrate configured to be connectable to the first substrate, and at least one bus bar connected to a circuit of the second substrate.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a plan view illustrating a bus bar module according to an embodiment; and

FIG. 2 is a plan view illustrating another bus bar module according to an embodiment.

### DETAILED DESCRIPTION OF THE PREFERRED EMBODIMENTS

Hereinafter, bus bar modules according to embodiments of the present invention will be described in detail with reference to the drawings. Note that the present invention is not limited by the present embodiments. In addition, the components in the following embodiments include those that can be easily imagined by those skilled in the art or those that are substantially the same.

### Embodiments

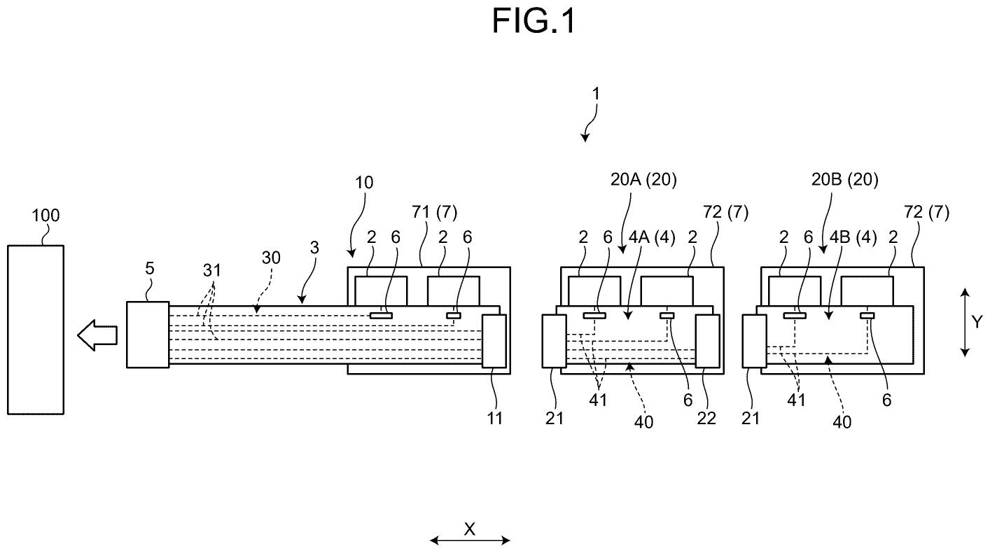

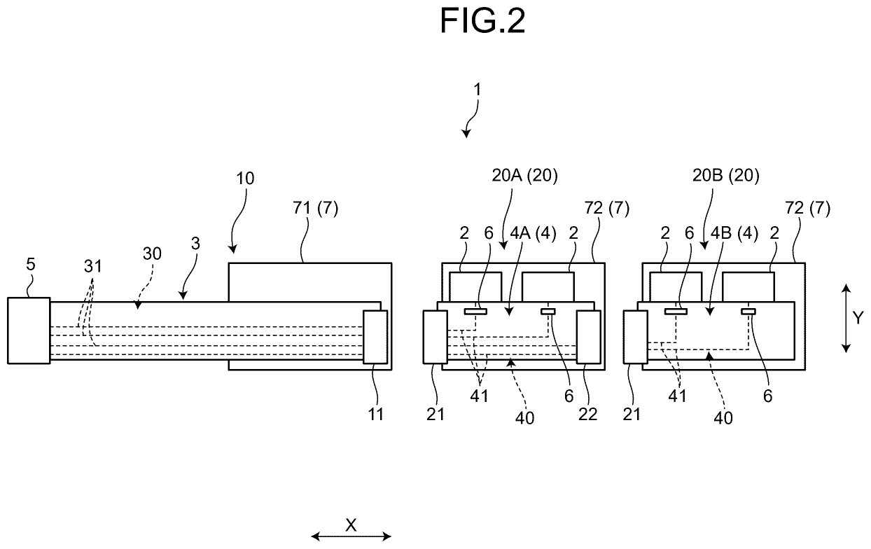

Embodiments will be described with reference to FIGS. 1 and 2. The present embodiments relate to bus bar modules. FIG. 1 is a plan view illustrating a bus bar module according to an embodiment, and FIG. 2 is a plan view illustrating another bus bar module according to an embodiment.

As illustrated in FIG. 1, the bus bar module 1 of the present embodiment includes a first module 10 and a second module 20. The bus bar module 1 is configured by connecting a first module 10 and at least one second module 20. The bus bar module 1 is assembled to, for example, a battery module including a plurality of battery cells.

The first module 10 includes a first substrate 3, a device connection unit 5, and at least one bus bar 2. The first module 10 is a module for interfacing with an external device 100 in the bus bar module 1. The first module 10 is a base module as a basic component of the bus bar module 1.

The first substrate 3 is a flexible printed circuit (FPC). The FPC includes a base film, a conductive layer, and a cover layer. The conductive layer is sandwiched between and protected by the base film and the cover layer. The conductive layer is, for example, a conductive metal foil, and has a circuit pattern including a plurality of detection lines 31. The first substrate 3 has flexibility and can be bent when being wired.

The device connection unit 5 connects a circuit 30 of the first substrate 3 to the external device 100. The device connection unit 5 is, for example, a connector having a terminal connected to the circuit 30. The external device 100 is, for example, a monitoring device that monitors the state of the battery module. The external device 100 is electrically connected to the battery module via the bus bar module 1 to monitor the state of the battery module.

The bus bar 2 is a plate-like member formed of a conductive metal. The bus bar 2 is fixed to, for example, an electrode of a battery cell, and electrically connects two battery cells. The first module 10 of the present embodiment includes two bus bars 2. The two bus bars 2 are arranged at an interval along an arrangement direction X. The arrangement direction X is, for example, a direction in which the battery cells are arranged in the battery module.

The circuit 30 of the first substrate 3 is a circuit pattern formed of a metal foil, and includes a plurality of detection lines 31. Among the plurality of detection lines 31, some detection lines 31 are connected to the bus bars 2 of the first module 10. More specifically, some of the detection lines 31 are connected to the bus bars 2 via chip fuses 6 mounted on the first substrate 3. Some of the other detection lines 31 among the plurality of detection lines 31 connect detection lines 41 of the second module 20 to the device connection unit 5.

The first module 10 includes a connection unit 11 disposed on the first substrate 3. The connection unit 11 is disposed at an end portion of the first substrate 3 on a side opposite to the side toward the device connection unit 5. The connection unit 11 is, for example, a connector having a terminal connected to the circuit 30. The connection unit 11 may be a joint configured to be solderable or weldable.

The second module 20 includes a second substrate 4 and a bus bar 2. The second module 20 is a module for connection or extension in the bus bar module 1. Similarly to the first substrate 3, the second substrate 4 is a flexible printed circuit (FPC).

The second substrate 4 includes a circuit 40. The circuit 40 is a circuit pattern formed of a metal foil, and includes at least one detection line 41. The bus bar module 1 of the present embodiment includes two second modules 20. In the following description, one of the two second modules 20 will be referred to as an extension module 20A, and the other one of the two second modules 20 will be referred to as a terminal module 20B.

The extension module 20A is interposed between the two modules to connect the two modules to each other. The extension module 20A can be interposed between the first module 10 and the second module 20, and can be interposed between the two second modules 20.

A second substrate 4A of the extension module 20A has a plurality of detection lines 41. Among the plurality of detection lines 41, some detection lines 41 are connected to bus bars 2 of the extension module 20A. More specifically, the detection lines 41 are connected to the bus bars 2 via chip fuses 6 mounted on the second substrate 4A. The extension module 20A of FIG. 1 includes two bus bars 2 arranged in the arrangement direction X, and two detection lines 41 corresponding thereto. Among the plurality of detection lines 41, some of the other detection lines 41 are connected to the detection lines 31 of the first module 10 and detection lines 41 of other second modules 20.

The extension module 20A includes a first connection unit 21 and a second connection unit 22. The first connection unit 21 is disposed at one end portion of the second substrate 4A, and the second connection unit 22 is disposed at the other end portion of the second substrate 4A. The first connection unit 21 and the second connection unit 22 are, for example, connectors having terminals connected to the circuit 40. The first connection unit 21 and the second connection unit 22 may be joints configured to be solderable or weldable.

The first connection unit 21 is configured to be connectable to the connection unit 11 of the first module 10. In a case where both the connection unit 11 and the first connection unit 21 are connectors, the first module 10 and the extension module 20A are coupled and electrically connected to each other by fitting the first connection unit 21 and the connection unit 11. The circuit 30 of the first module 10 is connected to the circuit 40 of the extension module 20A via the connection unit 11 and the first connection unit 21. In a case where both the connection unit 11 and the first connection unit 21 are joints, the connection unit 11 and the first connection unit 21 are joined together by soldering or welding.

In the extension module 20A, the second connection unit 22 may be configured to be connectable to a first connection unit 21. In this case, the bus bar module 1 may include a plurality of extension modules 20A. For example, a plurality of extension modules 20A may be interposed between the first module 10 and the terminal module 20B.

The terminal module 20B is a module connected to a terminal of the bus bar module 1 in the arrangement direction X. The terminal module 20B is configured to be connectable to the first module 10 and to be connectable to the extension module 20A.

A second substrate 4B of the terminal module 20B includes a circuit 40. The circuit 40 of the second substrate 4B includes at least one detection line 41. The terminal module 20B of FIG. 1 has two bus bars 2 arranged in the arrangement direction X and two detection lines 41 corresponding thereto. The detection lines 41 of the terminal module 20B are connected to the bus bars 2 via chip fuses 6 mounted on the second substrate 4B.

The terminal module 20B has a first connection unit 21. The first connection unit 21 is disposed at one end portion of the second substrate 4B. The first connection unit 21 of the terminal module 20B is configured, for example, similarly to the first connection unit 21 of the extension module 20A. The first connection unit 21 of the terminal module 20B is, for example, a connector having a terminal connected to the circuit 40. The first connection unit 21 may be a joint portion configured to be solderable or weldable. The first connection unit 21 of the terminal module 20B is configured to be connectable to the second connection unit 22 of the extension module 20A. The first connection unit 21 of the terminal module 20B may be configured to be connectable to the connection unit 11 of the first module 10.

The bus bar module 1 of the present embodiment includes a case 7 that accommodates the first substrate 3 and the second substrate 4. The case 7 is divided into a first case 71 and a second case 72. The first case 71 and the second case 72 are formed of, for example, an insulating synthetic resin. The first case 71 accommodates the first substrate 3. The second case 72 accommodates at least one second substrate 4. In the exemplified case 7, one second case 72 accommodates one second substrate 4. That is, the case 7 includes second cases 72 corresponding to the number of second modules 20.

In a case where the first module 10 includes a bus bar 2, the first case 71 is formed to accommodate the first substrate 3 and the bus bar 2. The second case 72 is formed to accommodate the second substrate 4 and the bus bar 2.

The first case 71 and the second case 72 may be configured to be connectable to each other. For example, the first case 71 and the second case 72 may have engagement portions engaged with each other along the arrangement direction X. For example, the second case 72 may have an engagement portion to be engaged with another second case 72 along the arrangement direction X.

The bus bar module 1 of FIG. 1 is configured by linearly connecting the first module 10, one extension module 20A, and one terminal module 20B. The circuit 40 of the second substrate 4 is connected to the circuit 30 of the first substrate 3, and is connected to the device connection unit 5 via the circuit 30. In a case where the bus bar module 1 includes a plurality of second modules 20, a second substrate 4 of one second module 20 is connected to the first substrate 3 via a second substrate 4 of another second module 20. For example, the second substrate 4B of the terminal module 20B is connected to the first substrate 3 of the first module 10 via the second substrate 4A of the extension module 20A.

The first module 10, the extension module 20A, and the terminal module 20B may be connected to each other before being assembled to the battery module. In this case, the first substrate 3, the second substrate 4A, and the second substrate 4B are connected to each other. The first case 71 and the two second cases 72 may be connected to constitute one case 7.

The first module 10, the extension module 20A, and the terminal module 20B may be individually assembled to the battery module. In other words, the modules 10, 20A, and 20B may be assembled to the battery module before the first substrate 3, the second substrate 4A, and the second substrate 4B are connected to each other. In this case, the substrates 3, 4A, and 4B may be connected to each other after the bus bars 2 of the modules 10, 20A, and 20B are assembled to the battery cells.

The first module 10 may include no bus bar 2. For example, as illustrated in FIG. 2, the first module 10 may include a first substrate 3, a device connection unit 5, and a connection unit 11, and may include no bus bar 2. In this case, all of the detection lines 31 of the circuit 30 may be configured to connect the detection lines 41 of the second module 20 to the device connection unit 5. In a case where the first module 10 includes no bus bar 2, the case 7 may include no first case 71.

As described above, the bus bar module 1 of the present embodiment includes a first module 10 and a second module 20. The first module 10 includes a first substrate 3 that is a flexible printed circuit, and a device connection unit 5 that connects a circuit 30 of the first substrate 3 to the external device 100. The second module 20 includes a second substrate 4 configured to be connectable to the first substrate 3, and at least one bus bar 2 connected to a circuit 40 of the second substrate 4. The second substrate 4 may be directly connectable to the first substrate 3, or may be connectable to the first substrate 3 via another second substrate 4. In the bus bar module 1 of the present embodiment, the flexible printed circuit is divided into the first substrate 3 and the second substrate 4. Therefore, it is possible to reduce the cost of the bus bar module 1 while using the flexible printed circuit.

The first module 10 of the present embodiment includes at least one bus bar 2 connected to the circuit 30 of the first substrate 3. Since both the first module 10 and the second module 20 have bus bars 2, it is possible to cope with an increase in length of the battery module.

The circuit 40 of the second substrate 4 of the present embodiment is connected to the device connection unit 5 via the circuit 30 of the first substrate 3. With such a configuration, it is possible to apply a circuit design similar to that in a case where all the bus bars 2 are connected to one flexible printed circuit.

The bus bar module 1 may have a plurality of second modules 20. In this case, the plurality of second modules 20 are configured to connect a second substrate 4 of one second module 20 and a second substrate 4 of another second module 20. With such a configuration, the bus bar module 1 including the plurality of second modules 20 is realized.

In a case where the bus bar module 1 includes a plurality of second modules 20, the second substrate 4 of one second module 20 is connected to the first substrate 3 via the second substrate 4 of another second module 20. With such a configuration, it is possible to flexibly design a circuit according to the battery module to be applied.

The bus bar module 1 may include a case 7 that accommodates the first substrate 3 and the second substrate 4. The case 7 may be divided into a first case 71 that accommodates the first substrate 3 and a second case 72 that accommodates the second substrate 4. In this case, the first case 71 is an element of the first module 10, and the second case 72 is an element of the second module 20. By dividing the case 7, it is possible to improve the transportability and handleability of the modules 10 and 20. For example, packing efficiency is improved at the time of transporting the modules 10 and 20.

The number of bus bars 2 included in the second module 20 is not limited to two. The second module 20 preferably includes at least one bus bar 2. The number of bus bars 2 included in the second module 20 may be an even number or an odd number. The first module 10 can include a bus bar 2. In a case where the first module 10 include bus bars 2, the number of bus bars 2 of the first module 10 may be an even number or an odd number.

In a case where the bus bar module 1 includes a plurality of second modules 20, each of the second modules 20 may include the same number of bus bars 2 as the other ones. For example, in a case where the bus bar module 1 includes a plurality of extension modules 20A, each of the extension modules 20A may include the same number of bus bars 2 as the other ones. The number of bus bars 2 included in the first module 10 and the number of bus bars 2 included in the second module 20 may be the same.

The bus bar module 1 may include no terminal module 20B. For example, the bus bar module 1 may include a first module 10 and an extension module 20A. In this case, a cover or the like for protecting the second connection unit 22 may be provided on the extension module 20A disposed at the terminal.

The embodiments disclosed above can be carried out in an appropriate combination.

A bus bar module according to the present embodiment includes: a first module including a first substrate that is a flexible printed circuit, and a device connection unit that connects a circuit of the first substrate to an external device; and a second module including a second substrate configured to be connectable to the first substrate, and at least one bus bar connected to a circuit of the second substrate. In the bus bar module according to the present embodiment, the flexible printed circuit is divided into the first substrate and the second substrate, and the first substrate and the second substrate are configured to be connectable to each other. Therefore, there is an effect in that the costs can be reduced when the flexible printed circuit is used.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A bus bar module comprising:
a first module including a first substrate that is a flexible printed circuit, and a device connection unit that connects a circuit of the first substrate to an external device; and
a second module including a second substrate configured to be connectable to the first substrate, and at least one bus bar connected to a circuit of the second substrate.

2. The bus bar module according to claim 1, wherein
the first module includes at least one bus bar connected to the circuit of the first substrate.

3. The bus bar module according to claim 1, wherein
the circuit of the second substrate is connected to the device connection unit via the circuit of the first substrate.

4. The bus bar module according to claim 1, comprising:
a plurality of the second modules, wherein
the plurality of the second modules are configured such that a second substrate of one of the second modules is connectable to a second substrate of another one of the second modules.

5. The bus bar module according to claim 1, comprising:
a plurality of the second modules, wherein
a second substrate of one of the second modules is connected to the first substrate via a second substrate of another one of the second modules.

6. The bus bar module according to claim 1, further comprising:
a case that accommodates the first substrate and the second substrate, wherein
the case is divided into a first case that accommodates the first substrate and a second case that accommodates the second substrate.
